(19) United States
(12) Patent Application Publication
(10) Pub. No.: US 2008/0210955 A1
(43) Pub. Date: Sep. 4, 2008

(54) Group III-V semiconductor device and method for producing the same

(75) Inventors: Toshiya Uemura, Aichi-ken (JP); Shigemi Horiuchi, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 12/010,653

(22) Filed: Jan. 28, 2008

(30) Foreign Application Priority Data
Jan. 29, 2007 (JP) 2007-018478

(51) Int. Cl. H01L 33/00

(52) U.S. Cl. 257/88; 438/28; 257/E33.023; 257/E33.06

(57) ABSTRACT

An object of the invention is to prevent short circuit at a side surface of a semiconductor device in the method for producing semiconductor devices including a laser lift-off step. The production method of the invention includes forming, on a sapphire substrate, a group III nitride semiconductor layer containing a plurality of semiconductor devices isolated from one another by a groove which reaches the substrate; forming a protective film for preventing short circuit on the top surface and side surfaces of the semiconductor layer and on the top surface of the sapphire substrate; forming a resin layer in the groove; bonding the semiconductor layer to a support substrate via a low-melting-point metal layer; and removing the sapphire substrate through the laser lift-off process. The resin layer functions as a support for the protective film, to thereby prevent cracking or chipping of the protective film. As a result, current leakage or short circuit, which would otherwise be caused by cracking or chipping of the protective film, can be prevented.

### BACKGROUND OF THE INVENTION

1. Field of the Invention

The present invention relates to a method for producing a semiconductor device which method includes growing an n-layer and a p-layer of a group III-V semiconductor on a growth substrate, bonding an electrode layer on the p-layer to a support substrate by use of solder, and removing the growth substrate through the laser lift-off process; and to a semiconductor device produced through the method. More particularly, the present invention relates to a method for producing a semiconductor device so as to prevent short circuit between side surfaces of a p-layer and an n-layer, and to protect the semiconductor device from cracking, which would otherwise occur in side surfaces of the device during the laser lift-off process; and to a semiconductor device structure produced through the method.

2. Background Art

In general, sapphire, which is chemically and thermally stable, has been employed as a substrate for the growth of a group III nitride semiconductor. However, since sapphire has no electrical conductivity, current cannot flow in a vertical direction of a semiconductor stacked structure including a sapphire substrate. Furthermore, sapphire has no clear cleavage plane, making dicing of a semiconductor structure on a sapphire substrate difficult. In addition, sapphire exhibits low thermal conductivity, and inhibits radiation of heat from a semiconductor device. In a semiconductor device including a semiconductor layer and a sapphire substrate, external quantum efficiency is low due to total reflection at the interface between the semiconductor layer and the substrate, or confinement of light in the semiconductor layer. Meanwhile, one conceivable technique for improving light extraction efficiency is forming irregularities on a light extraction surface. However, a sapphire substrate encounters difficulty in such a processing.

One technique known to solve such a problem is the laser lift-off process, which is used for separation and removal of a sapphire substrate through laser beam radiation.

Japanese Patent Application Laid-Open (kokai) No. 2005-333130 discloses a method in which a group III nitride semiconductor device is formed on a sapphire substrate; grooves are formed in the device through etching for separating the device into chips; forming electrodes on each chip; and each group III nitride semiconductor device grown on the sapphire substrate is bonded to a support substrate, followed by the laser lift-off process. Japanese Patent Application Laid-Open (kokai) No. 2005-333130 describes that cracking in the group III nitride semiconductor device—which would otherwise caused by thermal expansion of gas remaining in the grooves through laser beam radiation—can be prevented by filling the grooves with a dielectric material for elimination of gas.

Japanese Kohyo Patent Publication No. 2005-522873 discloses a method in which grooves are filled with a photoresist; and, instead of bonding between a group III nitride semiconductor device and a support substrate, a metal layer is formed on the group III nitride semiconductor device, followed by the laser lift-off process. This patent document describes that grooves are filled with a photoresist for the purpose of preventing a metal from entering the grooves during formation of a layer of the metal.

Japanese Patent Application Laid-Open (kokai) No. 2006-135321 discloses a method in which a protective film of, for example, SiO₂ or Al₂O₃, and a seed metal film are formed on inclined side surfaces of a semiconductor device; and a metal layer is formed on grooves and the semiconductor device, followed by the laser lift-off process.

Japanese Patent Application Laid-Open (kokai) No. 2006-310657 discloses that a resin is injected to cavities between a semiconductor layer and a support substrate after completion of the lift-off process so as to prevent cracking of the semiconductor layer during dicing.

When device separation is carried out through forming grooves in a semiconductor layer, which grooves reach a base, metallic dust or a like substance produced during a dicing step may be deposited on the side surfaces of the semiconductor layer exposed through formation of the grooves, resulting in current leakage or short circuit. In order to prevent such undesired deposition, insulating film is formed on the bottom surface and side surfaces of each groove. Since the insulating film is not sustained by a support, the film may be cracked or chipped after the laser lift-off process.

### SUMMARY OF THE INVENTION

Thus, an object of the present invention is to prevent current leakage and short circuit, which would otherwise occur at side surfaces of a semiconductor device, in the course of production of a semiconductor device including forming semiconductor devices on a base, which devices are separated from one another through provision of grooves which reach the base in a semiconductor layer; bonding each semiconductor device to a support substrate via a low-melting-point metal layer; and removing the base through the laser lift-off process.

Accordingly, in a first aspect of the present invention, there is provided a method for producing a group III-V semiconductor device, the method comprising

forming, on a base, a plurality of semiconductor devices isolated from one another by a groove which reaches the base, each semiconductor device having on the top surface thereof a p-electrode and a layer for preventing diffusion of a metal of low melting point (hereinafter such a layer may be referred to as a “low-melting-point metal diffusion preventing layer”);

forming, a protective film comprising a dielectric material, so as to cover at least a side surface of each semiconductor device;

forming a resin layer on a portion of the base corresponding to the bottom surface of the groove;

bonding the semiconductor device to a conductive support substrate via a low-melting-point metal layer; and

removing the base through the laser lift-off process.

The protective film preferably has a thickness of 100 nm to 500 nm. The side-surface protective film may be formed through, for example, plasma CVD. When the top surface of the semiconductor device has a region on which neither the p-electrode nor the low-melting-point metal diffusion preventing layer is formed, the side-surface protective film may be formed to cover the region. In addition to the side surfaces, the protective film may be formed on the entire surface of a base exposed to the bottom surfaces of the grooves, or on a portion of the bottom surfaces of grooves so as to cover the periphery of a semiconductor layer. The protective film is provided in order to prevent current leakage and short circuit, which would otherwise occur at side surfaces of a semiconductor device.

The p-electrode is preferably made of a metal having high optical reflectance and low contact resistance; for example, Ag, Rh, Pt, Ru, or an alloy containing such a metal as a primary component. Alternatively, the p-electrode may comprise, for example, Ni, an Ni alloy, or an Au alloy; or may comprise a composite layer including a transparent electrode film (e.g., ITO film) and a highly reflective metal film. The low-melting-point metal diffusion preventing layer may comprise, for example, a Ti/Ni-containing multi-layer film (e.g., Ti/Ni/Au film), or a W/Pt-containing multi-layer film (e.g., W/Pt/Au film). The low-melting-point metal diffusion preventing layer is provided for preventing diffusion therethrough of a metal constituting the low-melting-point metal layer. The low-melting-point metal layer may comprise a eutectic metal layer (e.g., an Au—Sn layer, an Au—Si layer, an Ag—Sn—Cu layer, or an Sn—Bi layer); or may comprise, for example, a layer of Au, Sn, or Cu (although such a metal is not a low-melting-point metal).

The support substrate comprises a conductive substrate such as an Si substrate, a GaAs substrate, a Cu substrate, or a Cu—W substrate.

The resin layer is provided to sustain the protective film after the laser lift-off process. By virtue of the resin layer, cracking or chipping of the protective film, which would otherwise occur after the laser lift-off process, can be prevented. As used herein, the phrase “forming a resin layer on a base” signifies that, when a protective film has been formed on a base, a resin layer is formed on the base via the protective film, and that, when no protective film has been formed on a base, a resin layer is formed directly on the base. Preferably, the resin layer is formed at least on the entire bottom surface of each groove, and has a thickness greater than that of the semiconductor device, in order to fully attain the supporting function of the resin layer.

A second aspect of the present invention is drawn to a specific embodiment of the production method according to the first aspect, wherein the resin layer is formed of a resin having a glass transition temperature of 200° C. or higher.

A third aspect of the present invention is drawn to a specific embodiment of the production method according to the first or second aspect, wherein the resin layer comprises a resin having a tensile elongation of 10% or higher and a volume resistivity of 1 GΩ·cm or higher.

A fourth aspect of the present invention is drawn to a specific embodiment of the production method according to any one of the first to third aspects, wherein the resin layer comprises a polyimide resin.

A fifth aspect of the present invention is drawn to a specific embodiment of the production method according to any one of the first to fourth aspects, wherein the resin layer is formed so that the layer has a thickness greater than that of the semiconductor device.

A sixth aspect of the present invention is drawn to a specific embodiment of the production method according to any one of the first to fifth aspects, wherein the protective film comprise any one selected from a group consisting silicon dioxide, silicon nitride, zirconium oxide, niobium oxide, and aluminum oxide.

A seventh aspect of the present invention is drawn to a specific embodiment of the production method according to any of the first to sixth aspects, wherein the low-melting-point metal layer comprises any one selected from a group consisting Au—Sn, Au—Si, Ag—Sn—Cu, and Sn—Bi.

An eighth aspect of the present invention is drawn to a specific embodiment of the production method according to any of the first to seventh aspects, wherein the semiconductor device comprises a group III nitride semiconductor.

A ninth aspect of the present invention is drawn to a specific embodiment of the production method according to any of the first to eighth aspects, wherein the semiconductor device comprises a light-emitting device.

In a tenth aspect of the present invention, the protective film is formed on the entire surface of a portion of the base exposed to the groove.

In an eleventh aspect of the present invention, the protective film is partially formed on a portion of the base exposed to the groove so as to cover the periphery of the semiconductor device, and the resin layer is formed on the portion of the base exposed to the groove so as to come into contact with the portion.

In a twelfth aspect of the present invention, there is provided a group III-V semiconductor device having a low-melting-point metal layer and being bonded to a conductive support substrate via the low-melting-point metal layer, wherein the device has a protective film comprising a dielectric material formed on a side surface of the device, and a resin layer comprising a polyimide resin formed on the side surface of the device via the protective film, and the polyimide resin has a glass transition temperature of 200° C. or higher, a volume resistivity of 1 GΩ·cm or higher, and a tensile elongation of 10% or higher.

A thirteenth aspect of the present invention is drawn to a specific embodiment of the semiconductor device according to the tenth aspect, wherein the protective film comprises any one selected from a group consisting silicon dioxide, silicon nitride, zirconium oxide, niobium oxide, and aluminum oxide.

A fourteenth aspect of the present invention is drawn to a specific embodiment of the semiconductor device according to the tenth or eleventh aspect, wherein the low-melting-point metal layer comprises any one selected from a group consisting Au—Sn, Au—Si, Ag—Sn—Cu, and Sn—Bi.

A fifteenth aspect of the present invention is drawn to a specific embodiment of the semiconductor device according to any of the tenth to twelfth aspects, wherein the semiconductor device comprises a group III nitride semiconductor.

A sixteenth aspect of the present invention is drawn to a specific embodiment of the semiconductor device according to any of the tenth to thirteenth aspects, wherein the semiconductor device is a light-emitting device.

In a seventeenth aspect of the present invention, the protective film is formed additionally on the entirety of a surface of the resin layer opposite the support substrate side and along the periphery of the resin layer.

In an eighteenth aspect of the present invention, the protective film is partially formed additionally on a surface of the resin layer opposite the support substrate side and along the periphery of the resin layer; and the semiconductor device has an isolation side surface formed of the resin layer, with no side surface of the protective film being exposed.

According to the first aspect of the invention, the resin layer formed on a portion of the base exposed to the bottom of the groove for isolating semiconductor devices functions as a support for the protective film. Therefore, cracking or chipping of the protective film, which would otherwise occur after the laser lift-off process, can be prevented. Thus, exposure of the side surfaces of the semiconductor device, which would otherwise be caused by chipping or cracking of the protective film, can be prevented, whereby current leakage and short circuit can be prevented. As a result, production yield of semiconductor devices can be enhanced.

According to the second aspect of the invention, the resin layer is formed of a resin having a glass transition temperature of 200° C. or higher. Thus, deterioration over time such as decomposition or discoloration can be prevented, and durability of the produced semiconductor devices can be enhanced by virtue of high heat resistance of the resin.

According to the third aspect of the invention, the resin layer is formed of a resin having a tensile elongation of 10% or higher. Thus, the resin layer readily collapses and spreads during bonding to a support substrate, ensuring satisfactory bonding performance. When the resin layer is formed of a resin having a volume resistivity of 1 GΩ·cm or higher, a satisfactory insulation property can be attained.

According to the eleventh aspect of the invention, during dicing by means of a tool such as a dicing blade to isolate semiconductor devices, the blade cuts the resin layer but does not cut the protective layer. Therefore, peeling of the protective layer during device isolation can be prevented.

According to the semiconductor devices of the twelfth to eighteenth aspects of the invention, a resin layer is formed on side surfaces of the semiconductor device via a protective film. Thus, cracking or chipping of the protective film as well as current leakage and short circuit can be prevented.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIGS. 1A to 1I are cross-sectional views of semiconductor structures for describing the steps of producing a light-emitting device of Embodiment 1; and

FIGS. 2A to 2F are cross-sectional views of semiconductor structures for describing the steps of producing a light-emitting device of Embodiment 2.

### DETAILED DESCRIPTION OF PREFERRED EMBODIMENTS

Referring to the drawings, specific embodiments of the present invention will next be described. However, the present invention is not limited to the embodiments.

### Embodiment 1

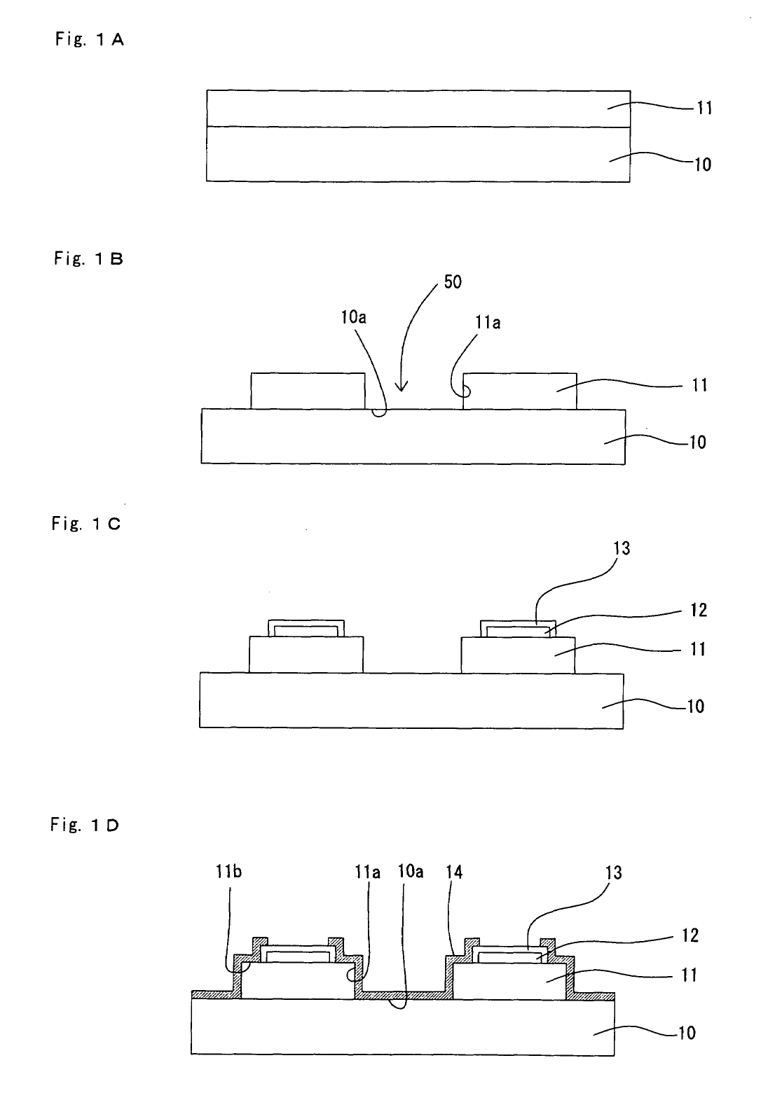

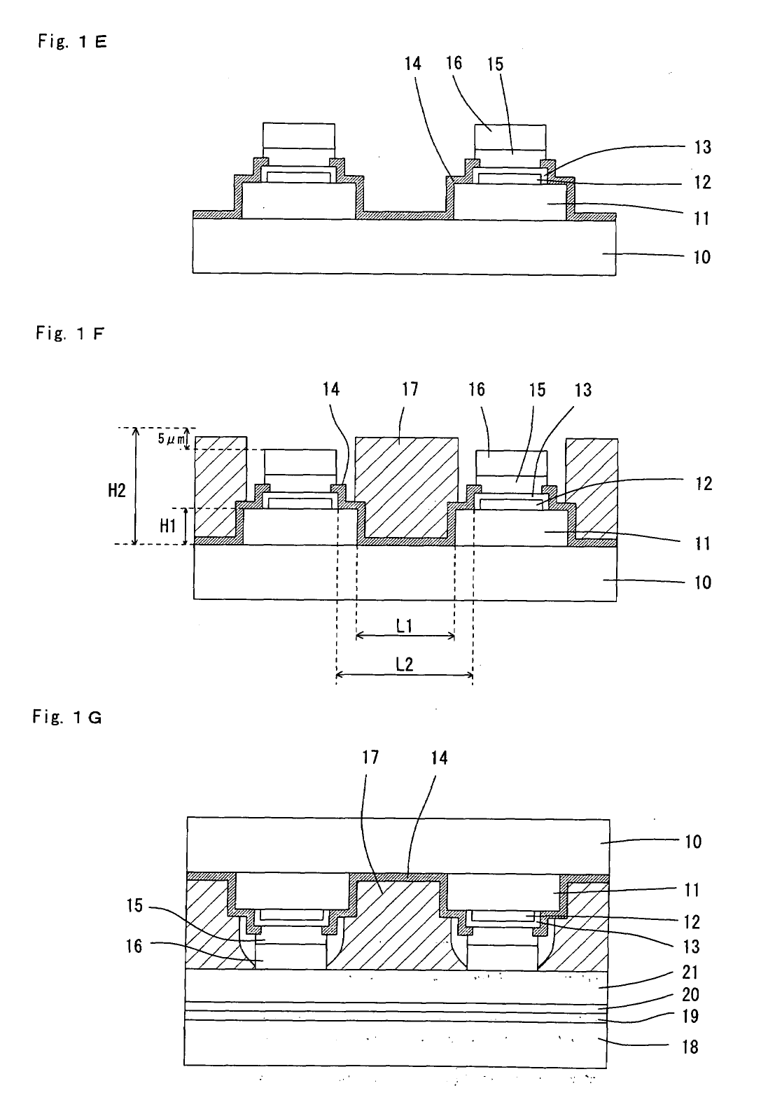

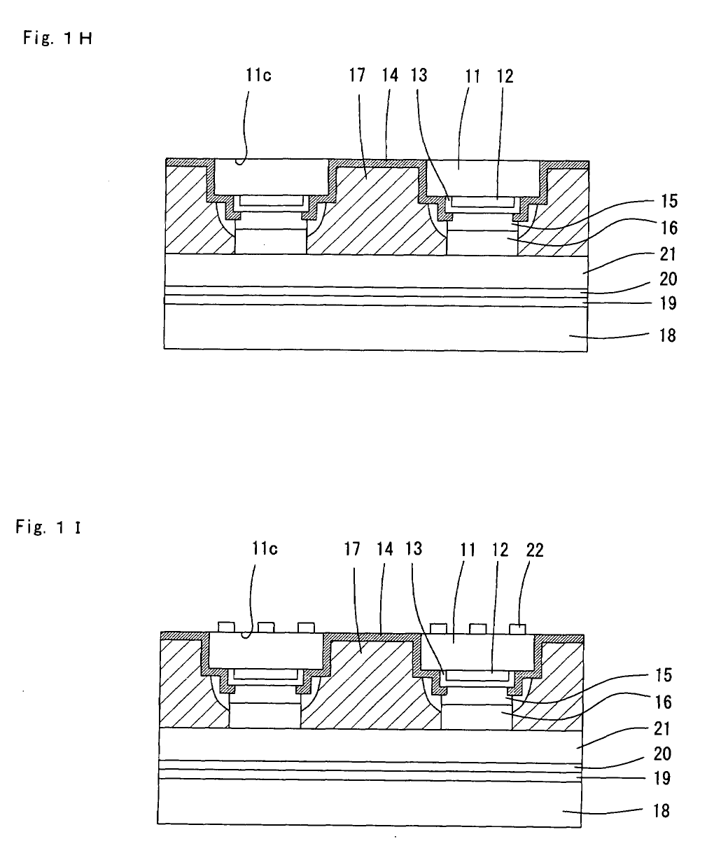

FIGS. 1A to 1I are cross-sectional views of semiconductor structures for describing the steps of producing a light-emitting device. With reference to FIGS. 1A to 1I, the steps of producing a light-emitting device will be described.

Firstly, a group III nitride semiconductor layer 11 is formed on a sapphire substrate 10 through epitaxial growth (FIG. 1A). The semiconductor layer 11 has a stacked structure including an n-layer (proximal to the sapphire substrate 10), an MQW layer on the n-layer, and a p-layer on the MQW layer.

Then, predetermined areas of the semiconductor layer 11 are dry-etched until a surface 10a of the sapphire substrate 10 is exposed, to thereby form a groove 50, whereby the semiconductor layer 11 is separated into semiconductor chips (FIG. 1B). A side surface 11a of each semiconductor layer 11 is not necessarily normal to the sapphire substrate 10 and may be slanted.

Subsequently, a p-electrode 12 is formed on a predetermined area of the semiconductor layer 11 through a lift-off process, and a metal ion diffusion preventing layer 13 is formed so as to cover the p-electrode 12 (FIG. 1C). The p-electrode 12 was formed from Ag—Pd—Cu, but may be formed from a metal having high optical reflectance and low contact resistance; for example, Ag, Rh, Pt, Ru, or an alloy containing such a metal as a primary component. Alternatively, the p-electrode may be made of, for example, Ni, an Ni alloy, or an Au alloy; or may be formed of a composite layer including a transparent electrode film (e.g., ITO film) and a highly reflective metal film. When the p-electrode 12 comprises at least Ag, the metal diffusion preventing layer 13 functions to prevent Ag ions from diffusing through the layer 13. In this embodiment because the p-electrode 12 comprises Ag, the metal diffusion preventing layer 13 is called as an Ag ion diffusion preventing layer 13. The Ag ion diffusion preventing layer 13 was formed from a multilayer film of Ti/Ni/Au/Al in which Ti, Ni, Au, and Al layers have a thickness of 100 nm, 500 nm, 100 nm, and 3 nm, respectively. Alternatively, the Ag ion diffusion preventing layer 13 may be formed of, for example, a Ti/Ni-containing multi-layer film, or a W/Pt-containing multi-layer film (e.g., W/Pt/Au film). Alternatively, the Ag ion diffusion preventing layer may be formed from a multilayer film of Ti/TiN/Ti or Ta/TaN/Ta in which Ti, TiNi, and Ti or Ta, TaN, and Ta layers have a thickness of 30 nm, 200 nm, and 100 nm, respectively.

Instead of performing the aforementioned steps (FIGS. 1A to 1C), a p-electrode 12 and an Ag ion diffusion preventing layer 13 may be formed on a predetermined area of the semiconductor layer 11 and, subsequently, the semiconductor layer 11 may be dry-etched until the sapphire substrate 10 is exposed, whereby the semiconductor layer 11 is separated into semiconductor chips.

Subsequently, a protective film 14 made of SiO₂ is integrally formed, through CVD, on a surface 10a of the sapphire substrate 10 exposed in the previous step (FIG. 1B), on side surfaces 11a of the semiconductor layer 11, on top surfaces 11b of the semiconductor layer 11 where the p-electrode 12 has not been formed, and on a predetermined area of the Ag ion diffusion preventing layer 13 (FIG. 1D). The protective film 14 prevents current leakage and short circuit at the side surfaces 11a of the semiconductor layer 11. The protective film 14 preferably has a thickness of about 100 nm to about 500 nm. When the thickness of 100 nm or less, adhesion between the semiconductor layer 11 and the protective film 14 disadvantageously decreases, whereas when the thickness is 500 nm or more, a considerably long time is required for etching performed in a subsequent patterning step. Both cases are not preferred. Other than SiO₂, Si₃N₄ (silicon nitride), ZrO₂ (zirconium oxide), NbO (niobium oxide), Al₂O₃ (aluminum oxide), etc. may also be used. Notably, the protective film 14 may be formed at least on the side surface 11a of the semiconductor layer 11, and is not necessarily formed in a manner as employed in Embodiment 1.

On the Ag ion diffusion preventing layer 13 and the protective film 14, a low-melting-point metal diffusion preventing layer 15 is formed. On the low-melting-point metal diffusion preventing layer 15, a low-melting-point metal layer 16 is formed (FIG. 1E). The low-melting-point metal diffusion preventing layer 15 is a multi-layer film of Ti/Ni/Au in which Ti, Ni, and Au layers have a thickness of 100 nm, 500 nm, and 50 nm, respectively. The low-melting-point metal layer 16 is formed of Au—Sn (Sn20%) and has a thickness of 3 μm. The low-melting-point metal layer 16 may be formed of a eutectic metal layer (e.g., an Au—Si layer, an Ag—Sn—Cu layer, or an Sn—Bi layer); or may be formed of, for example, a layer of Au, Sn, or Cu (although such a metal is not a low-melting-point metal). The low-melting-point metal diffusion preventing layer 15 and the low-melting-point metal layer 16 are formed into predetermined patterns through photolithography.

Then, a resin layer 17 made of a polyimide resin having a glass transition temperature of 200° C. or higher, a volume resistivity of 1 GΩ·cm or higher, and a tensile elongation of 10% or higher is formed on the protective film 14 (FIG. 1F). The resin layer functions as a support for the protective film 14 and prevents cracking or chipping of the protective film 14 after a subsequent laser lift-off step. When the glass transition temperature is 200° C. or higher, deterioration over time such as decomposition or discoloration can be prevented, and durability of the produced semiconductor devices can be enhanced by virtue of high heat resistance of the resin. A volume resistivity of 1 GΩ·cm or higher is preferred, since a satisfactory insulation property can be attained.

The resin layer 17 preferably has a thickness falling within a range of a minimum thickness H1 (i.e., thickness of the semiconductor layer 11) to a maximum thickness H2 (i.e., total thickness of the semiconductor layer 11, p-electrode 12, Ag ion diffusion preventing layers 13, low-melting-point metal diffusion preventing layer 15, and low-melting-point metal layer 16 plus 5 μm). When the resin layer 17 has a thickness of H1 or less, supporting function is poor, whereas when the resin layer 17 has a thickness of H2 or more, bonding of the layer to a support substrate in the subsequent step may fail to be attained. Needless to say, both cases are not preferred. In addition, the resin layer 17 is preferably formed at least within a width L1, which is equivalent to an interval between two chips in the semiconductor layer 11. When the resin layer has a width narrower than L1, supporting function is disadvantageously poor. Preferably, the resin layer 17 has a maximum width smaller than L2, which is equivalent to an interval between two Ag ion diffusion preventing layers 13 formed on the semiconductor layer 11. When the width is greater than L2, in the case where the resin layer 17 collapses during bonding to a support substrate and spreads in the plane direction in the subsequent step, a space sufficient for receiving the resin may fail to be ensured, which is not preferred.

Subsequently, on the top surface of the support substrate 18 made of Si, a contact layer 19, a low-melting-point metal diffusion preventing layer 20, and a low-melting-point metal layer 21 are formed. The plane including the low-melting-point metal layer 16 is bonded to that including the low-melting-point metal layer 21, through hot-pressing at 300° C. and a load of 30 kgf/cm² (FIG. 1G). During press bonding, the resin layer 17 slightly collapses to spread in the plane direction. Therefore, the resin for forming the resin layer 17 preferably has a tensile elongation of 10% or more. The contact layer 19 is an Al layer having a thickness of 300 nm. The low-melting-point metal diffusion preventing layer 20 is identical to the low-melting-point metal diffusion preventing layer 15, and the low-melting-point metal layer 21 is identical to the low-melting-point metal layer 16. Other than Si, the support substrate 18 may be formed of GaAs, Cu, or Cu—W. The Ag ion diffusion preventing layers 13 prevents diffusion of Ag ions from the p-electrode 12. The low-melting-point metal diffusion preventing layers 15, and 20 prevent diffusion of metals forming the low-melting-point metal layers 16 and 21 through the low-melting-point metal diffusion preventing layers 15, and 20.

Through the laser lift-off technique, the sapphire substrate 10 is removed (FIG. 1H). In this step, the sapphire substrate 10 side of a wafer is irradiated with a KrF laser light (wavelength: 248 nm) at 0.7 J/cm² or higher. Through laser irradiation, the semiconductor layer 11 is melted at an interface between the sapphire substrate 10 and the semiconductor layer 11, whereby the sapphire substrate 10 is removed from the wafer. After removal of the sapphire substrate, an exposed surface 11c is washed with hydrochloric acid, followed by wet-etching with an aqueous KOH solution at 50° C., to thereby roughen the surface to increase an efficiency of light output.

After completion of the laser lift-off process, the resin layer 17 functions as a support for the protective film 14, whereby cracking or chipping of the protective film 14 per se is prevented. Therefore, according to the present invention, exposure of the side surface 11a of the semiconductor layer 11, which would otherwise be caused by cracking or chipping of the protective film 14, can be prevented, whereby current leakage and short circuit are prevented.

Subsequently, a lattice-shape V/Al/Ti/Ni/Au n-electrode 22 is formed on the surface 11c, which has been bonded to the sapphire substrate 10 (FIG. 1I). In the n-electrode, the V, Al, Ti, Ni, and Au layers have a thickness of 15 nm, 150 nm, 30 nm, 500 nm, and 500 nm, respectively. Thereafter, through a dicing step, light-emitting devices formed on the support substrate 18 and having a surface 11c (on the side of n-electrode 22) as a light-extracting plane can be produced.

### Embodiment 2

In Embodiment 1, the protective film 14 is formed on the entirety of the exposed surface 10a of the sapphire substrate 10. A characteristic feature of Embodiment 2 is that the protective film 14 is partially formed on the exposed surface 10a of the sapphire substrate 10, and that a resin layer 17 is provided such that the layer is joined to the exposed surface 10a of the sapphire substrate 10.

Hereinafter, the same reference numerals as employed in Embodiment 1 are used to denote the same members. As shown in FIGS. 1A to 1C, a semiconductor layer 11 is formed on the sapphire substrate 10, and a predetermined area of the semiconductor layer 11 is etched to thereby form a groove 50, to which a surface 10a of the sapphire substrate 10 is exposed. A p-electrode 12 is formed on the semiconductor layer 11, and a Ag ion diffusion preventing layer 13 is formed so as to cover the p-electrode 12.

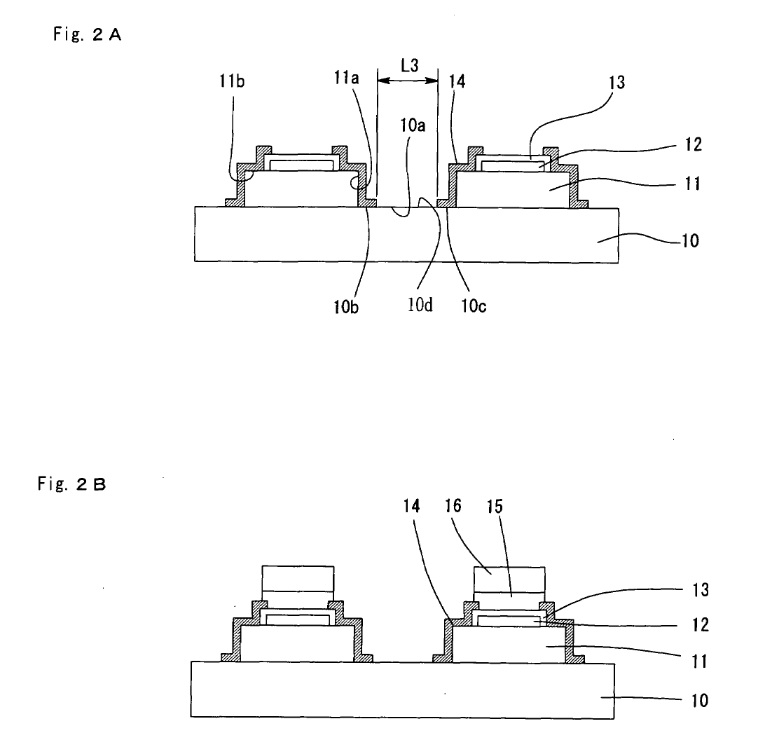

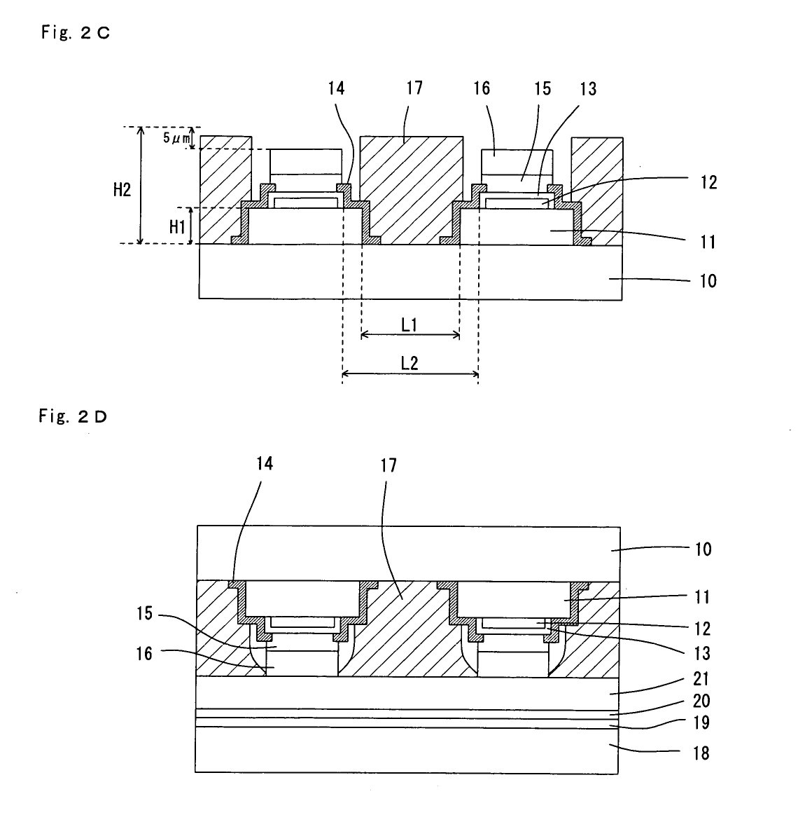

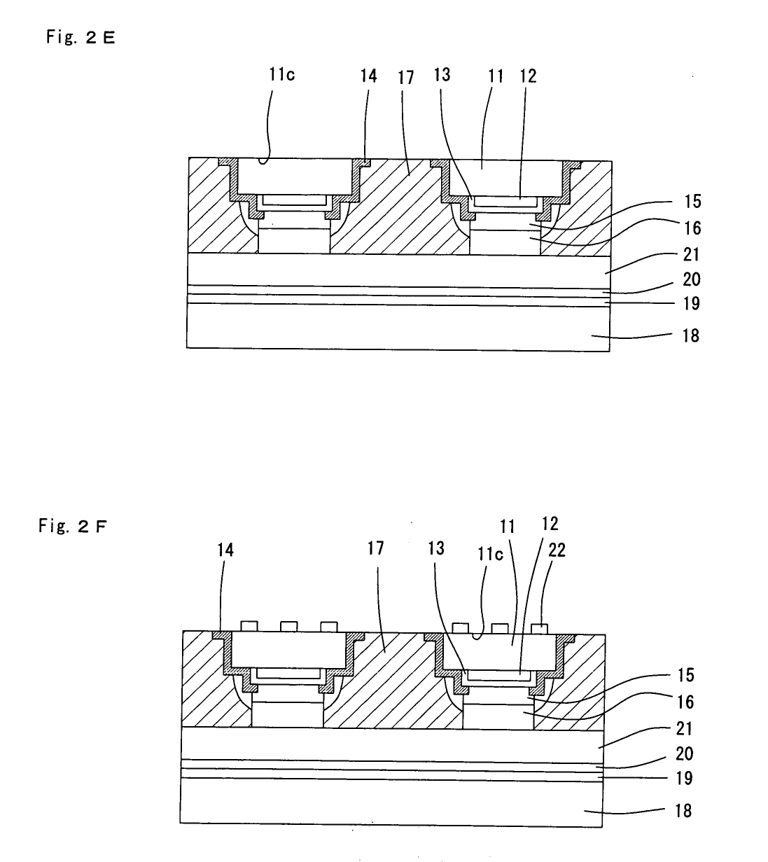

Subsequently, a protective film 14 made of SiO₂ is integrally formed, through CVD, on portions 10b and 10c of the exposed surface 10a of the sapphire substrate 10 which surround the periphery of the semiconductor layer 11, on side surfaces 11a of the semiconductor layer 11, on top surfaces 11b of the semiconductor layer 11 where the p-electrode 12 has not been formed, and on a predetermined area of the Ag ion diffusion preventing layer 13 (FIG. 2A). Through the above procedure, a main exposed surface 10d of the sapphire substrate 10 which is not covered with the protective film 14 is formed. The main exposed surface 10d has a width L3, which is wider than a device splitting width; i.e., the width of a dicer blade for use in splitting the semiconductor layer 11 to produce device chips or the width of a scriber for chipping in a subsequent step.

Subsequently, a low-melting-point metal diffusion preventing layer 15 is formed on the Ag ion diffusion preventing layer 13 and on a portion of the protective film 14, and a low-melting-point metal layer 16 is formed on the low-melting-point metal diffusion preventing layer 15 (FIG. 2B). Then, a resin layer 17 made of a polyimide resin having a glass transition temperature of 200° C. or higher, a volume resistivity of 1 GΩ·cm or higher, and a tensile elongation of 10% or higher is formed on the protective film 14 and on the main exposed surface 10d of the sapphire substrate 10 (FIG. 2C). The resin layer 17 functions as a support for the protective film 14 and prevents cracking or chipping of the protective film 14 after a subsequent laser lift-off step. In addition, the resin layer 17 covers the protective film 14 such that a side surface of the protective film 14 is not exposed to a device isolation plane after splitting each individual device chips. By virtue of the resin layer, delamination of the protective film 14 from the semiconductor layer 11 during separation of the semiconductor layer 11 to split each individual device chips can be prevented.

Subsequently, on the top surface of the support substrate 18 made of Si, a contact layer 19, a low-melting-point metal diffusion preventing layer 20, and a low-melting-point metal layer 21 are formed. The plane including the low-melting-point metal layer 16 is bonded to that including the low-melting-point metal layer 21, through hot-pressing at 300° C. and a load of 30 kgf/cm² (FIG. 2D). During press bonding, the resin layer 17 slightly collapses to spread in the plane direction. Subsequently, through the laser lift-off technique, the sapphire substrate 10 is removed (FIG. 2E). After removal of the sapphire substrate 10, an exposed surface 11c is washed with hydrochloric acid, followed by wet-etching, to thereby roughen the surface to increase an efficiency of light output.

After completion of the laser lift-off process, the resin layer 17 functions as a support for the protective film 14, whereby cracking or chipping of the protective film 14 per se is prevented. Therefore, according to the present invention, exposure of the side surface 11a of the semiconductor layer 11, which would otherwise be caused by cracking or chipping of the protective film 14, can be prevented, whereby current leakage and short circuit are prevented.

Subsequently, a lattice-shape n-electrode 22 is formed on the surface 11c, which has been bonded to the sapphire substrate 10 (FIG. 2F). Thereafter, through a dicing step, light-emitting devices formed on the support substrate 18 and having a surface 11c (on the side of n-electrode 22) as a light-extracting plane can be produced. In the dicing step, the width L3 shown in FIG. 2A of the main exposed surface 10d; i.e., width L3 of a contact portion between the resin layer 17 and the sapphire substrate 10, is wider than the width required for dicing. Therefore, a blade does not come in contact with the protective film 14 during dicing. Since the width L3 of the main exposed surface 10d is wide enough for dicer chipping, the protective film 14 receives no cutting stress during device separation. Therefore, delamination of the protective film 14 from the semiconductor layer 11 during separation of the semiconductor layer 11 to split each individual device chips can be prevented. In addition, since a side surface of the protective film 14 is not exposed to a device isolation plane by coverage with the resin layer 17, peeling of the protective film 14 during handling the support substrate 18 after removal of the sapphire substrate 10 and during handling device chips after splitting the support substrate 18 to produce each individual device chips can be prevented.

A portion of the protective film 14 is in contact with the exposed surface 10a of the sapphire substrate 10 such that the contact width of the portion is not less than the thickness of the protective film 14. That is, the protective film 14 may be bent from a side surface of the semiconductor layer 11 toward the exposed surface 10a of the sapphire substrate 10. The maximum value of the width L3 of the exposed surface 10d of the sapphire substrate 10 is a value which ensures the above bending state of the protective film 14.

The other features of Embodiment 2 are the same as those employed in Embodiment 1.

With reference to the aforementioned Embodiments, the method for producing a light-emitting device has been described. However, the present invention can be applied not only to the method for producing a light-emitting device but also to any methods for producing semiconductor devices employing a laser lift-off technique. Other than Group III nitride semiconductor devices, the present invention may also be applied to semiconductor devices of a Group III-V semiconductor such as GaAs GaP. The pattern of the n-electrode is not limited to a lattice, and any pattern such as a stripe may be employed, so long as the pattern does not impede light extraction through the top surface.

As described hereinabove, according to the present invention, production yield of semiconductor devices through a laser lift-off technique can be enhanced.

What is claimed is:

1. A method for producing a group III-V semiconductor device, the method comprising
forming, on a base, a plurality of semiconductor devices isolated from one another by a groove which reaches the base, each semiconductor device having on the top surface thereof a p-electrode and a low-melting-point metal diffusion preventing layer;
forming a protective film comprising a dielectric material, so as to cover at least a side surface of each semiconductor device;
forming a resin layer on a portion of the base corresponding to the bottom surface of the groove;
bonding the semiconductor device to a conductive support substrate via a low-melting-point metal layer; and
removing the base through the laser lift-off process.

2. A method for producing a semiconductor device as described in claim 1, wherein the resin layer comprises a resin having a glass transition temperature of 200° C. or higher.

3. A method for producing a semiconductor device as described in claim 1, wherein the resin layer comprises a resin having a tensile elongation of 10% or higher and a volume resistivity of 1 GΩ·cm or higher.

4. A method for producing a semiconductor device as described in claim 1, wherein the resin layer comprises a polyimide resin.

5. A method for producing a semiconductor device as described in claim 1, wherein the resin layer is formed so that the layer has a thickness greater than that of the semiconductor device.

6. A method for producing a semiconductor device as described in claim 1, wherein the protective film comprises any one selected from a group consisting silicon dioxide, silicon nitride, zirconium oxide, niobium oxide, and aluminum oxide.

7. A method for producing a semiconductor device as described in claim 1, wherein the low-melting-point metal layer comprises any one selected from a group consisting Au—Sn, Au—Si, Ag—Sn—Cu, and Sn—Bi.

8. A method for producing semiconductor device as described in claim 1, wherein the semiconductor device comprises a group III nitride semiconductor.

9. A method for producing a semiconductor device as described in claim 1, wherein the semiconductor device comprises a light-emitting device.

10. A method for producing a semiconductor device as described in claim 1, wherein the protective film is formed on the entire surface of a portion of the base exposed to the groove.

11. A method for producing a semiconductor device as described in claim 1, wherein the protective film is partially formed on a portion of the base exposed to the groove so as to cover the periphery of the semiconductor device, and the resin layer is formed on the portion of the base exposed to the groove so as to come into contact with the portion.

12. A group III-V semiconductor device having a low-melting-point metal layer and being bonded to a conductive support substrate via the low-melting-point metal layer, wherein
the device has a protective film comprising a dielectric material formed on a side surface of the device, and a resin layer comprising a polyimide resin formed on the side surface of the device via the protective film, and
the polyimide resin has a glass transition temperature of 200° C. or higher, a volume resistivity of 1 GΩ·cm or higher, and a tensile elongation of 10% or higher.

13. A semiconductor device as described in claim 12, wherein the protective film comprises any one selected from a group consisting silicon dioxide, silicon nitride, zirconium oxide, niobium oxide, and aluminum oxide.

14. A semiconductor device as described in claim 12, wherein the low-melting-point metal layer comprises any one selected from a group consisting Au—Sn, Au—Si, Ag—Sn—Cu, and Sn—Bi.

15. A semiconductor device as described in claim 12, wherein the semiconductor device comprises a group III nitride semiconductor.

16. A semiconductor device as described in claim 12, wherein the semiconductor device is a light-emitting device.

17. A semiconductor device as described in claim 12, wherein the protective film is formed additionally on the entirety of a surface of the resin layer opposite the support substrate side and along the periphery of the resin layer.

18. A semiconductor device as described in claim 13, wherein the protective film is formed additionally on the entirety of a surface of the resin layer opposite the support substrate side and along the periphery of the resin layer.

19. A semiconductor device as described in claim 12, wherein the protective film is partially formed additionally on a surface of the resin layer opposite the support substrate side and along the periphery of the resin layer; and the semiconductor device has an isolation side surface formed of the resin layer, with no side surface of the protective film being exposed.

20. A semiconductor device as described in claim 13, wherein the protective film is partially formed additionally on a surface of the resin layer opposite the support substrate side and along the periphery of the resin layer; and the semiconductor device has an isolation side surface formed of the resin layer, with no side surface of the protective film being exposed.
